(19) United States
(12) Patent Application Publication
(10) Pub. No.: US 2015/0257307 A1
(43) Pub. Date: Sep. 10, 2015

(54) HEAT SINK

(71) Applicant: NEC Corporation, Tokyo (JP)

(72) Inventor: Tomoyuki MITSUI, Tokyo (JP)

(73) Assignee: NEC Corporation

(21) Appl. No.: 14/635,121

(22) Filed: Mar. 2, 2015

(30) Foreign Application Priority Data
Mar. 5, 2014 (JP) 2014-042839

(51) Int. Cl. H05K 7/20

(52) U.S. Cl. CPC H05K 7/20418

(57) ABSTRACT

Provided is a heat sink capable of easing restrictions on direction of cooling air for acquiring a sufficient cooling effect. The heat sink includes a base heat sink including a circular female screw structure at a position opposite to a mounting position of a cooled component, and a cylindrical heat sink including a male screw structure configured to be engaged with the female screw structure of the base heat sink on a side face and a pin fin structure protruded roughly vertically in one bottom surface.

This application is based upon and claims the benefit of priority from Japanese Patent Application No. 2014-042839, filed on Mar. 5, 2014, the disclosure of which is incorporated herein in its entirety by reference.

### TECHNICAL FIELD

The present invention relates to a cooling technology of a solid-state device, and more particularly to a heat sink.

### BACKGROUND ART

Concerning a cooling technology of a solid-state device, there are known various related technologies.

For example, Patent Literature 1 discloses a heat sink assembly for a solid-state device. A heat sink member in the Patent Literature 1 includes a threaded base. The threaded base is configured to be received in a threaded bore formed in a top wall of an adaptor. The adaptor is configured to clamp spaced marginal edges of an electronic device package.

The electronic device package is inserted into opposite grooves of the adaptor. Then, a heat sink is screwed down toward the package until a flat bottom surface of the heat sink base is firmly biased against the top surface of the electronic device package and thermally coupled thereto. The heat sink includes a plurality of generally circular “fins” spaced along a generally cylindrical core or helical “fins” extending from the core.

Patent Literature 2 discloses a cooling technology for radiating, to the outside of a shield case, heat generated from a semiconductor device mounted on a printed circuit board housed in the shield case provided to block electromagnetic waves. An electronic device of the Patent Literature 2 is configured by sandwiching a heat conductive sheet between an upper surface of the semiconductor device mounted on the printed circuit board housed in the shield case and a tip surface of a screw member (heat radiating member).

The heat generated from the semiconductor device is conducted to the heat conductive sheet and the screw member. Then, the heat conducted to the screw member is radiated to the outside of the shield case from a base end or the like of the screw member projected from an outer surface of a case cap.

The Patent Literature 2 also discloses a finny heat radiating fin formed in the screw member.

### CITATION LIST

### Patent Literature

[Patent Literature 1] Japanese Translation of PCT International Application Publication No. 08-507655

[Patent Literature 2] Japanese Laid-open Patent Publication No. 2006-179712

### SUMMARY

An object of the present invention is to provide a heat sink capable of solving a problem that a sufficient cooling effect may not be provided depending on a direction of cooling air.

A heat sink according to an exemplary aspect of the invention includes

a base heat sink including a circular female screw structure at a position opposite to a mounting position of a cooled component; and

a cylindrical heat sink including a male screw structure configured to be engaged with the female screw structure on a side face and a first pin fin structure protruded roughly vertically in one bottom surface.

### BRIEF DESCRIPTION OF THE DRAWINGS

Exemplary features and advantages of the present invention will become apparent from the following detailed description when taken with the accompanying drawings in which:

FIG. 1 is an isometric diagram illustrating a configuration of a heat sink according to a first exemplary embodiment of the present invention;

FIG. 2 is an isometric diagram illustrating a state where a base heat sink and a cylindrical heat sink are engaged with each other according to the first exemplary embodiment;

FIG. 3 is an isometric diagram illustrating a configuration of a heat sink according to a second exemplary embodiment of the present invention;

FIG. 4 is a diagram illustrating a procedure of mounting the heat sink to a printed circuit board according to the second exemplary embodiment;

FIG. 5 is a front view illustrating a state where the heat sink is mounted to the printed circuit board according to the second exemplary embodiment;

FIG. 6 is an isometric diagram illustrating an example of a dimple-formed pin fin according to the second exemplary embodiment;

FIG. 7 is an isometric diagram illustrating an example of a cylindrical pin fin according to the second exemplary embodiment;

FIG. 8 is an isometric diagram illustrating an example of a spherical-headed pin fin according to the second exemplary embodiment;

FIG. 9 is an isometric diagram illustrating a configuration of a heat sink according to a third exemplary embodiment of the present invention;

FIG. 10 is a front view illustrating a state where the heat sink is mounted to a printed circuit board according to the third exemplary embodiment;

FIG. 11 is a front view illustrating the state where the heat sink is mounted to the printed circuit board according to the third exemplary embodiment; and

FIG. 12 is a front view illustrating a state where the heat sink is mounted to both surfaces of the printed circuit board according to the present invention.

### EXEMPLARY EMBODIMENT

The exemplary embodiments of the present invention will be described in detail with reference to the drawings. Throughout the drawings and the exemplary embodiments described herein, the same and similar components are denoted by the same or corresponding reference signs, and description thereof will be appropriately omitted.

### First Exemplary Embodiment

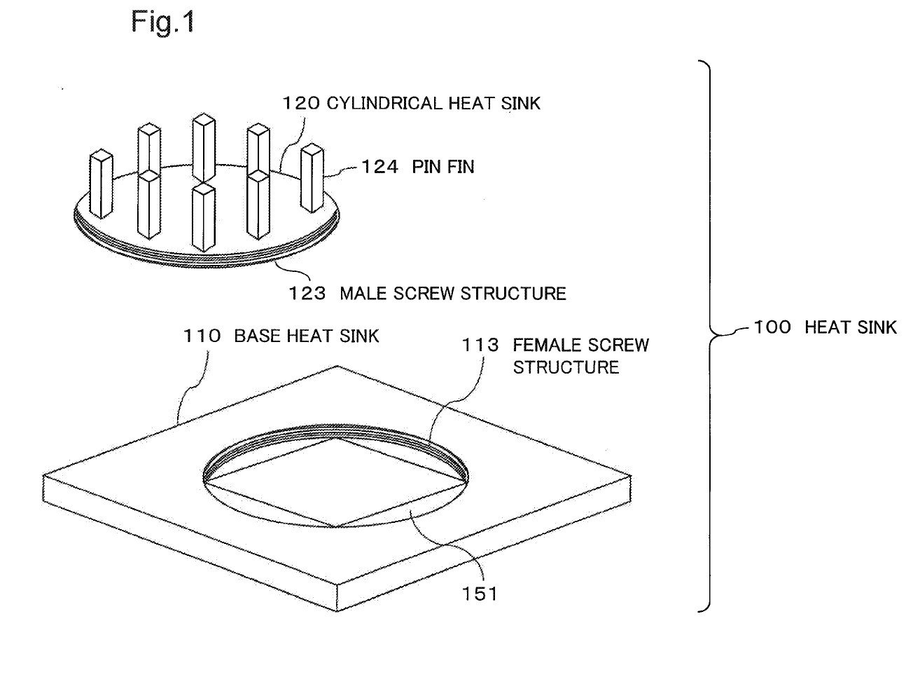

FIG. 1 is an isometric diagram illustrating a configuration of a heat sink 100 according to a first exemplary embodiment of the present invention.

As illustrated in FIG. 1, the heat sink 100 according to the present exemplary embodiment includes a base heat sink 110 and a cylindrical heat sink 120.

The base heat sink 110 includes a circular female screw structure 113 at a position 151 opposite to a mounting position of a cooled component (not illustrated).

The cylindrical heat sink 120 includes a male screw structure 123 configured to be engaged with the female screw structure 113 on a side face. The cylindrical heat sink 120 includes pin fins 124 projected roughly vertically in one bottom surface (upper bottom surface in FIG. 1). In other words, the cylindrical heat sink 120 includes a pin fin structure (first pin fin structure) on one bottom surface.

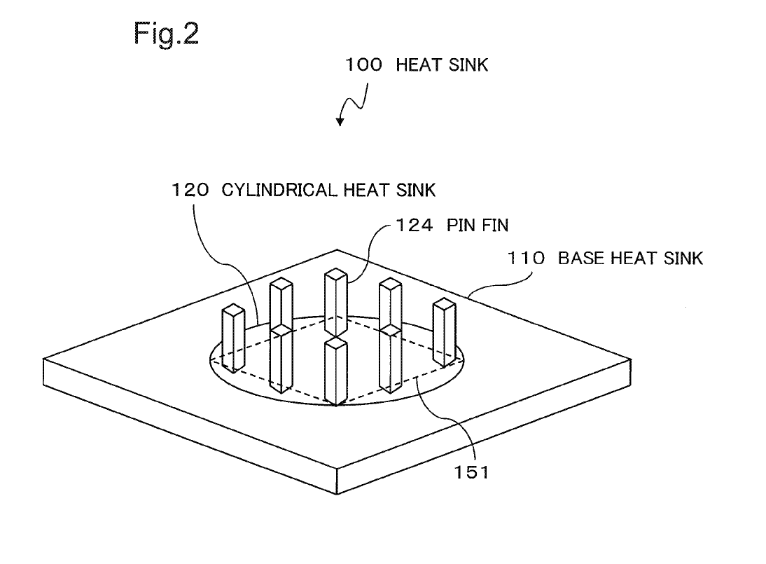

FIG. 2 is an isometric diagram illustrating a state where the base heat sink 110 and the cylindrical heat sink 120 are engaged with each other.

The base heat sink 110 and the cylindrical heat sink 120 are engaged with each other by a screw structure. Accordingly, the cylindrical heat sink 120 is located on the lower side relatively to the base heat sink 110 in accordance with the amount of rotation in FIG. 2. In other words, the cylindrical heat sink 120 and a distance between the cooled component (not illustrated) determining the position relative to the base heat sink 110 is adjustable by the amount of rotation of the cylindrical heat sink 120.

Therefore, the heat sink 100 can sufficiently crush heat radiating grease without any dependence on component tolerance or variation in height of the cooled component (e.g., LSI (Large-Scale Integration)). In other words, the heat sink 100 can achieve desired thermal coupling with the cooled component.

The heat sink 100 enables the heat sink to be fixed without using any spring. Thus, the numbers of springs and accompanying components can be reduced.

The heat sink 100 is higher in reliability than that when a spring is used for heat sink fixing. It is because when the spring is used for heat sink fixing, if stronger vibration or shocks than a spring load are applied, for example, in transit, peeling-off or air trapping of the heat radiating grease between the heat sink 100 and the cooled component may occur. Such peeling-off or air trapping may cause reduction of performance of the heat radiating grease. The heat sink 100 can prevent such peeling-off or air trapping occurring.

When the spring is used for heat sink fixing, an excessive load may be applied on the cooled component (e.g., when cooled component is LSI, high LSI bump load may cause bump destruction) due to the component tolerance or the variation in height of the cooled component. The heat sink 100 can prevent such an excessive load.

The pin fins 124 of the cylindrical heat sink 120 receive cooling air not only from an arbitrary direction of 360 degrees on a plane parallel to the bottom surface of the cylindrical heat sink 120 but also from an arbitrary direction of a hemisphere with respect to the bottom surface without any interference with each other.

An effect of the present exemplary embodiment described above is that restrictions on direction of cooling air for acquiring a sufficient cooling effect can be eased.

The reason is that the cylindrical heat sink 120 engaged with the base heat sink 110 by the screw structure includes the pin fins 124 vertical to the bottom surface.

### Second Exemplary Embodiment

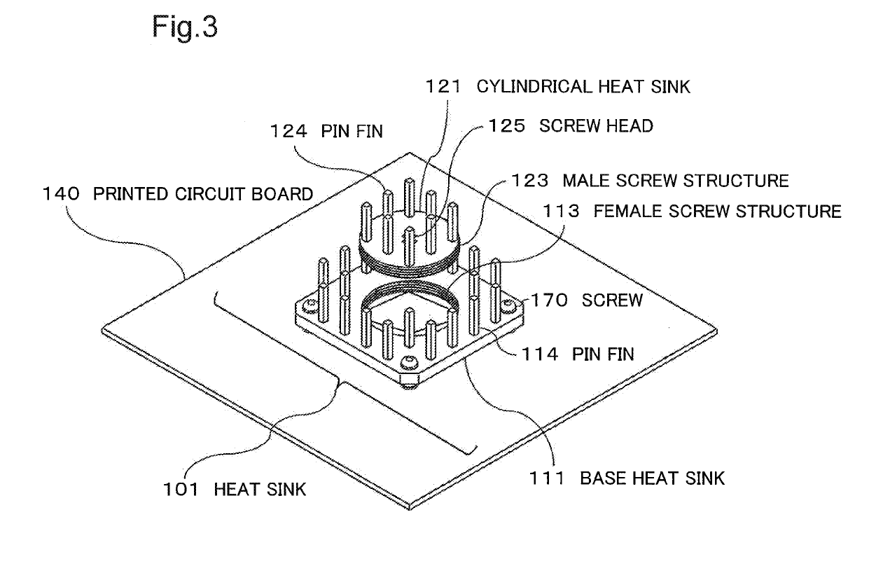

FIG. 3 is an isometric diagram illustrating a configuration of a heat sink 101 according to a second exemplary embodiment of the present invention.

As illustrated in FIG. 3, the heat sink 101 according to the present exemplary embodiment includes a base heat sink 111 and a cylindrical heat sink 121.

The base heat sink 111 further includes a pin fin 114 (second pin fin structure) different from the base heat sink 110 of the first exemplary embodiment.

FIG. 3 illustrates a state where the base heat sink 111 is fixed to a printed circuit board 140 by screws 170.

The cylindrical heat sink 121 includes driver screw heads 125 different from the cylindrical heat sink 120 of the first exemplary embodiment.

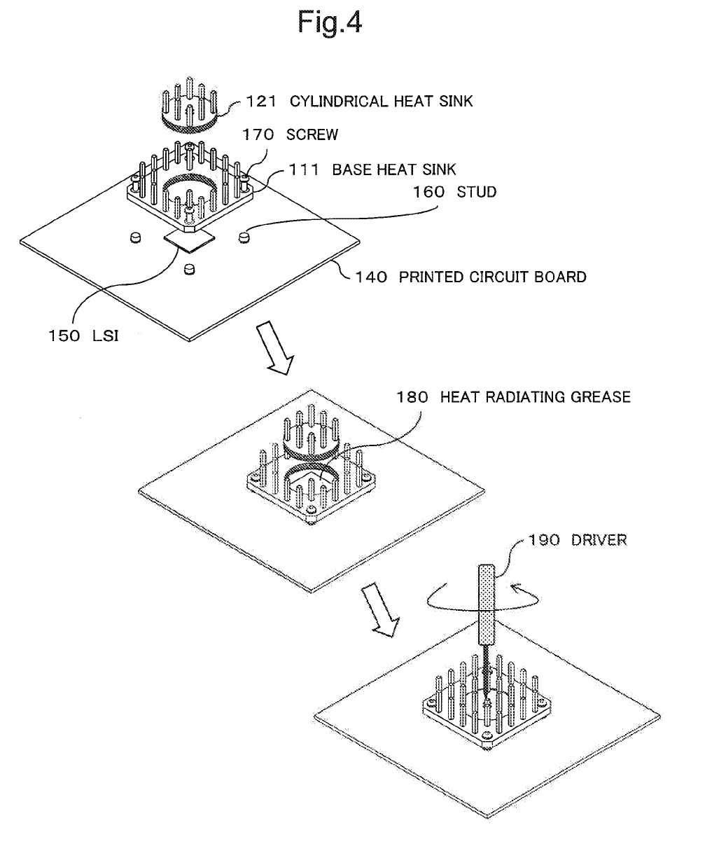

FIG. 4 is a diagram illustrating a procedure of mounting the heat sink 101 to the printed circuit board 140.

Referring to FIG. 4, LSI (also referred to as cooled component) 150 is mounted on the printed circuit board 140.

The printed circuit board 140 includes studs 160 fixed around the LSI 150.

The base heat sink 111 includes holes to insert the screws 170. The screw 170 is inserted into the hole to fix the base heat sink 111 to the stud 160.

After the base heat sink 111 is fixed, heat radiating grease 180 is applied on an upper surface of the LSI 150.

Then, the male screw structure 123 of the cylindrical heat sink 121 is positioned at the female screw structure 113 of the base heat sink 111, the cylindrical heat sink 121 is rotated by a driver 190, and the cylindrical heat sink 121 is fixed to the base heat sink 111.

A circle of the bottom surface of the cylindrical heat sink 121 is set equal in size to an circumscribed circle of the upper surface of the LSI 150. It is for maximizing a contact surface of the cylindrical heat sink 121 with the LSI 150. Thus, when the contact surface of the cylindrical heat sink 121 with the LSI 150 may not be maximized in order to acquire a necessary cooling effect, the circle of the bottom surface of the cylindrical heat sink 121 may be smaller than the circumscribed circle of the upper surface of the LSI 150.

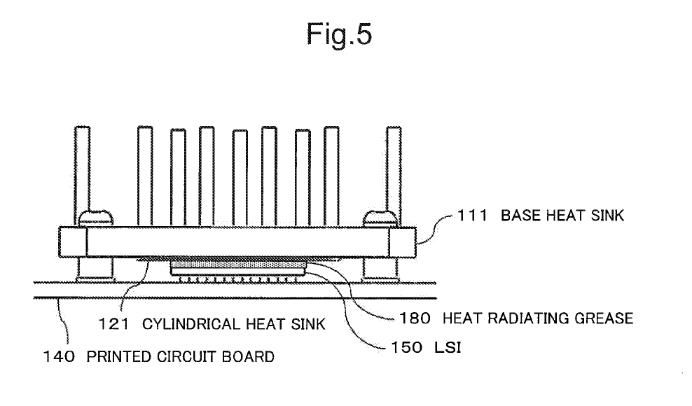

FIG. 5 is a front view illustrating a state where the heat sink 101 is mounted to the printed circuit board 140.

In this state, the amount of rotations of the cylindrical heat sink 121 is adjusted to adjust a distance between the cylindrical heat sink 121 and the LSI 150. In other words, a thickness of the heat radiating grease 180 applied between the cylindrical heat sink 121 and the LSI 150 is set in accordance with the amount of rotations.

The heat radiating grease 180 may be applied before the base heat sink 111 is fixed.

In place of the heat radiating grease 180, an elastic heat radiating sheet may be used. In such a case, it is required to be careful in order to prevent shifting or the like of the heat radiating sheet caused by rotation.

For the driver 190, a normal driver may be used, or a torque driver may be used to facilitate distance adjustment.

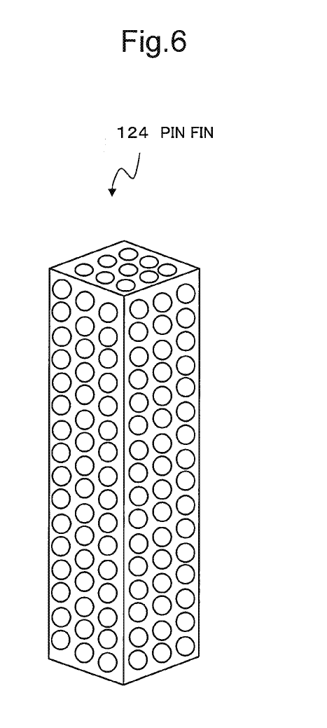

Dimples may be formed on respective surfaces of the pin fins 124 and 114. FIG. 6 is an isometric diagram illustrating an example of the dimple-formed pin fin 124.

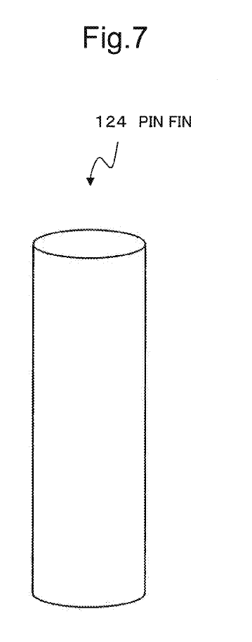

Shapes of the pin fins 124 and 114 may be similar to or different from each other. For example, the shapes are square prism. The shapes may be cylindrical. The shapes may be also columnar to continuously or discontinuously change in section vertical to an axis. FIG. 7 is an isometric diagram illustrating an example of the cylindrical pin fin 124.

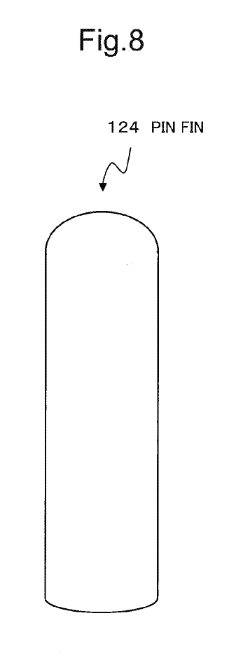

Heads of the pin fins 124 and 114 may be spherical having arbitrary curvatures or planar. FIG. 8 is an isometric diagram illustrating an example of the spherical-headed pin fin 124.

A first effect of the present exemplary embodiment described above is that a cooling effect can be further improved in addition to the effect of the first exemplary embodiment.

The reason is that the base heat sink 111 includes the pin fin 114.

Further, the reason is that the dimples are formed on the surfaces of the pin fins 124 and 114 to increase surface areas of the pin fins 124 and 114, respectively.

A second effect of the present exemplary embodiment described above is that noise generated by the cooling air can be reduced.

The reason is that the pin fins 124 and 114 are cylindrical. Further, another reason is that the heads of the pin fins 124 and 114 are spherical.

### Third Exemplary Embodiment

Next, a third exemplary embodiment of the present invention will be described in detail with reference to the drawings. Hereinafter, description of contents overlapping those described above will be omitted without making the description of the present exemplary embodiment unclear.

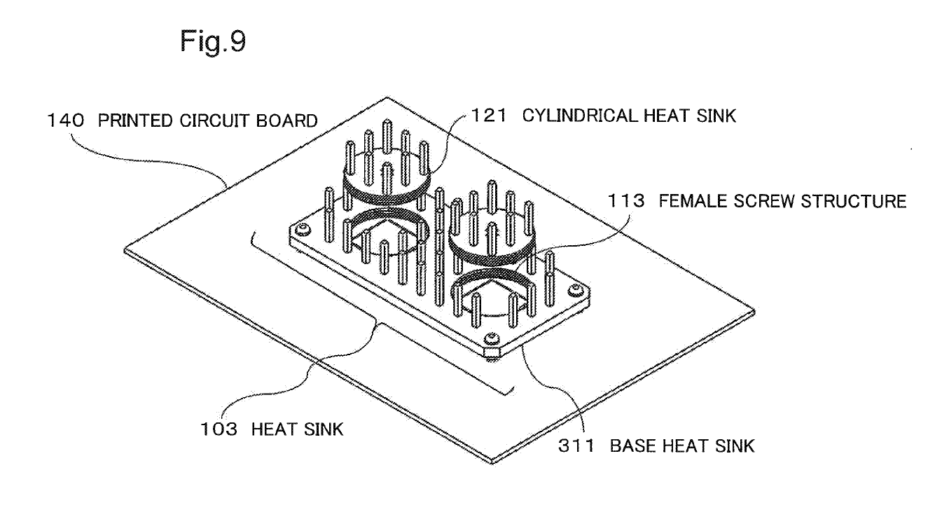

FIG. 9 is an isometric diagram illustrating a configuration of a heat sink 103 according to the third exemplary embodiment of the present invention.

As illustrated in FIG. 9, the heat sink 103 according to the present exemplary embodiment includes a base heat sink 311 and a cylindrical heat sink 121. The heat sink 103 includes two cylindrical heat sinks 121.

The base heat sink 311 includes two female screw structures 113 different from the base heat sink 111 of the first exemplary embodiment.

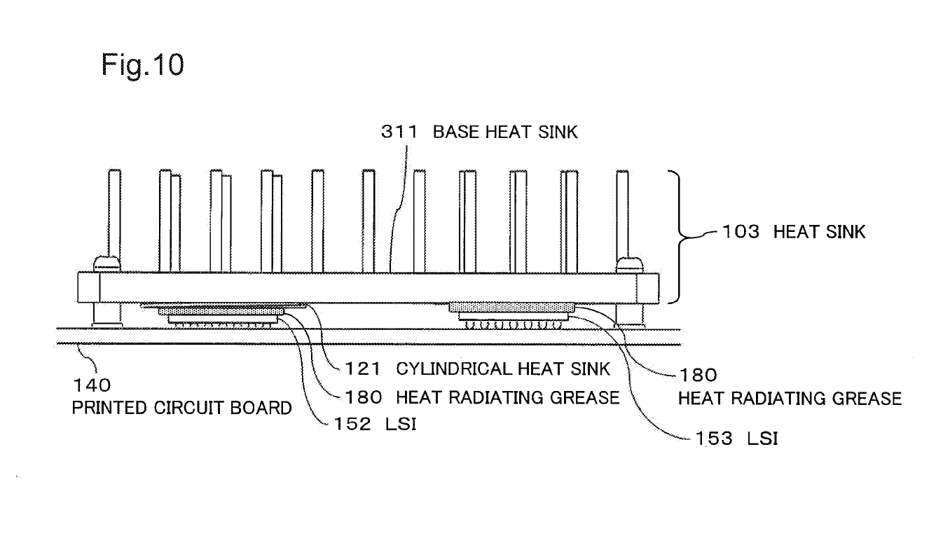

FIG. 10 is a front view illustrating a state where the heat sink 103 is mounted to a printed circuit board 140.

In FIG. 10, a left LSI 152 is a short LSI, while a right LSI 153 is a tall LSI. The amount of rotations of the cylindrical heat sink 121 corresponding to each of the LSI 152 and LSI 153 is adjusted to adjust a distance between the cylindrical heat sink 121 and each of the LSI 152 and LSI 153.

As illustrated in FIG. 10, the cylindrical heat sink 121 corresponding to the LSI 152 protrudes to a lower side of the base heat sink 311, while the cylindrical heat sink 121 corresponding to the LSI 153 hides behind the base heat sink 311. In other words, by adjusting the amounts of rotations of the cylindrical heat sinks 121, distances between the cylindrical heat sinks 121 and each of the LSI 152 and LSI 153 can be adjusted to be equal.

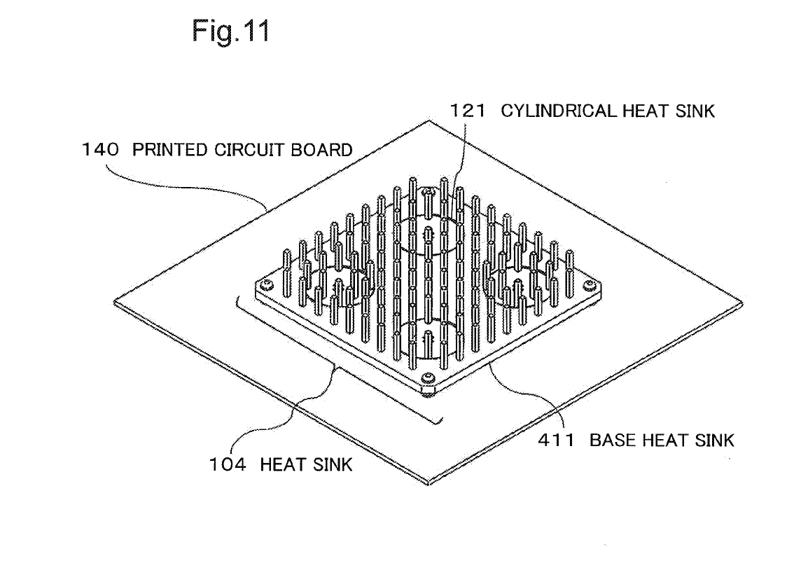

The heat sink may include a base heat sink 411 including three or more female screw structures 113 and the cylindrical heat sinks 121 which are equal in number to the female screw structures 113 so as to correspond to three or more cooled components. FIG. 11 is an isometric diagram illustrating a state where a heat sink 104 corresponding to four LSIs 150 is mounted to the printed circuit board 140.

An effect of the present exemplary embodiment described above is that effects similar to those of the second exemplary embodiment can be provided in accordance with a plurality of cooled components such as a multichip module.

The reason is that each of the base heat sink 311 and 411 includes the plurality of female screw structures 113.

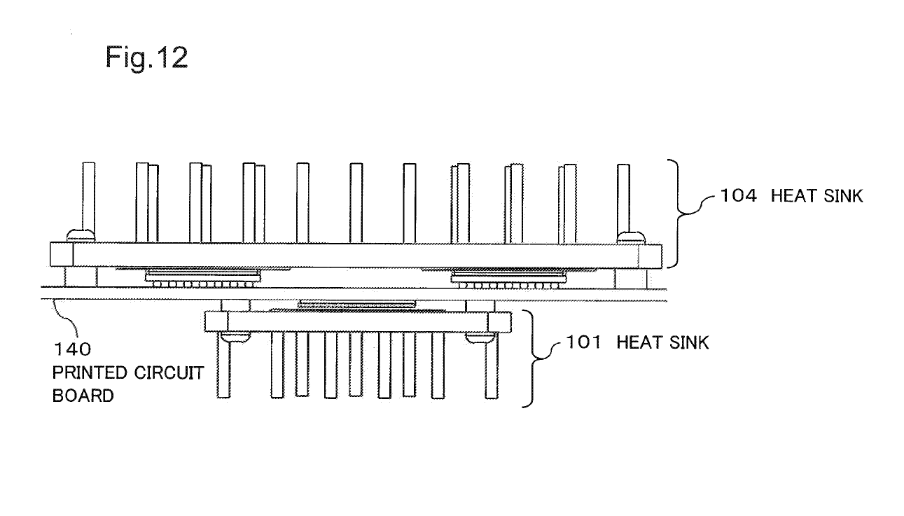

The heat sinks 100, 101, 103, and 104 of the respective exemplary embodiments may be mounted to both surfaces of the printed circuit board 140. FIG. 12 is a front view illustrating a state where the heat sinks 104 and 101 are mounted to both surfaces of the printed circuit board 140.

The technology described in the Background Art describe above has a problem, specifically, a sufficient cooling effect may not be provided depending on a direction of cooling air. In other words, the technology described in the Background Art describe above has a problem of restrictions on direction of the cooling air.

The reason is that in the heat sink of the Patent Literature 1 and the heat radiating member of the Patent Literature 2, the fin members for improving the heat radiating effect are formed to spread in a radial direction of the cylindrical heat sink or the heat radiating member. In other words, when cooling air is blown from an axial direction of the cylindrical heat sink or the heat radiating member, cooling air may not be sufficiently blown against portions other than the fin member of an upper end.

The present invention is advantageous in that restrictions on direction of cooling air for acquiring a sufficient cooling effect can be eased.

While the present invention has been described with reference to the exemplary embodiment, the present invention is not limited to the above-mentioned exemplary embodiment. Various changes, which a person skilled in the art can understand, can be added to the composition and the details of the invention of the present application in the scope of the invention of the present application.

### REFERENCE SIGNS LIST

100 Heat sink
101 Heat sink
103 Heat sink
104 Heat sink
110 Base heat sink
111 Base heat sink
113 Female screw structure
114 Pin fin
120 Cylindrical heat sink
121 Cylindrical heat sink
123 Male screw structure
124 Pin fin
125 Screw head
140 Printed circuit board
150 LSI
151 Position
152 LSI
153 LSI
160 Stud
180 Heat radiating grease
190 Driver
311 Base heat sink
411 Base heat sink

1. A heat sink comprising:
a base heat sink including a circular female screw structure at a position opposite to a mounting position of a cooled component; and
a cylindrical heat sink including a male screw structure configured to be engaged with the female screw structure on a side face and a first pin fin structure protruded roughly vertically in one bottom surface.

2. The heat sink according to claim 1, wherein the base heat sink includes a second pin fin structure protruded in the same direction as that of the first pin fin structure of the cylindrical heat sink in a state where the cylindrical heat sink is engaged with the base heat sink.

3. The heat sink according to claim 1, wherein a pin fin of the first pin fin structure is cylindrical.

4. The heat sink according to claim 1, wherein a head of a pin fin of the first pin fin structure is spherical.
